(19) United States
(12) Patent Application Publication
(10) Pub. No.: US 2026/0211314 A1
(43) Pub. Date: Jul. 23, 2026

(54) METHOD FOR REMOVING DEFECT

(71) Applicant: Samsung Electronics Co., Ltd., Suwon-si (KR)

(72) Inventors: Yoonki HWANG, Suwon-si (KR); Jeongjae SEO, Suwon-si (KR); Sang-Hyeon LEE, Suwon-si (KR)

(73) Assignee: Samsung Electronics Co., Ltd., Suwon-si (KR)

(21) Appl. No.: 19/269,210

(22) Filed: Jul. 15, 2025

(30) Foreign Application Priority Data
Jan. 23, 2025 (KR) 10-2025-0010017

(51) Int. Cl. G03F 1/74; G03F 7/00

(52) U.S. Cl. CPC G03F 1/74; G03F 7/7065

(57) ABSTRACT

Provided is a method for removing a defect, including loading a target object into a chamber, acquiring information about the defect on the target object, depositing a ferromagnetic material layer on the defect, and removing the defect and the deposited ferromagnetic material layer from the target object.

### CROSS-REFERENCE TO RELATED APPLICATION

This application claims priority to and benefit of Korean Patent Application No. 10-2025-0010017, filed in the Korean Intellectual Property Office on Jan. 23, 2025, the entire contents of which are hereby incorporated by reference.

### BACKGROUND

Example embodiments relate to a method for removing a defect.

As the semiconductor industry continues to advance and manufacture semiconductor devices with higher density, smaller defects occurring during the manufacturing process can have a larger and more significant impact on the performance and/or reliability of the devices. Such defects may occur during exposure, etching, deposition, chemical mechanical polishing (CMP) processes, etc. If not removed, the defects may cause a malfunction of the semiconductor devices, thereby reducing yield and/or increasing process cost.

Particularly, in the manufacturing process of semiconductor devices, it may be advantageous to accurately recognize the location and size of defects and remove them effectively. Related defect removal technologies have shortcomings of incomplete elimination of defects and/or lower process efficiency.

The information described above is intended to improve understanding of the background of the present disclosure, and may include information that does not constitute the related art.

### SUMMARY

In order to solve one or more problems (e.g., the problems described above and/or other problems not explicitly described herein), some example embodiments of the present disclosure provide a method for removing a defect.

In some example embodiments, a method for removing a defect is provided, which may include loading a target object into a chamber, acquiring information about the defect on the target object, depositing a ferromagnetic material layer on the defect, and removing the defect and the deposited ferromagnetic material layer from the target object.

In some example embodiments, a method for removing a defect is provided, which may include loading a mask into a chamber, acquiring information about the defect on a pattern structure of the mask, depositing a ferromagnetic material layer on the defect, removing the defect and the deposited ferromagnetic material layer from the mask using a defect transporter, the defect transporter including a defect collecting unit configured to generate a magnetic force, and moving the defect and the deposited ferromagnetic material layer to a collector.

In some example embodiments, a method for removing a defect is provided, which may include loading a target object into a chamber, acquiring information about a center position of the defect on the target object, converting an interior of the chamber into a vacuum state by pumping the interior of the chamber using a vacuum pump connected to the chamber, determining a deposition position of a ferromagnetic material layer by applying an offset distance in a horizontal direction from the center position of the defect, depositing the ferromagnetic material layer at the determined deposition position within the target object using a beam deposition device, removing the defect and the deposited ferromagnetic material layer from the target object using a defect transporter, the defect transporter configured to generate a magnetic force, and moving the defect and the deposited ferromagnetic material layer to a collector.

According to some example embodiments of the present disclosure, a defect on a target object can be effectively removed without a cleaning operation, by depositing a ferromagnetic material layer on the defect and removing the defect using a magnetic force.

According to some example embodiments of the present disclosure, after the ferromagnetic material layer is deposited on the defect and removed using the magnetic force, and the magnetic force is deactivated so that the defect is easily separated from the collection unit. Accordingly, the collection unit for removing defects can be reused for several times, which can effectively reduce process cost and effort.

According to some example embodiments of the present disclosure, by depositing the ferromagnetic material layer at a position offset in a horizontal direction from the center point of the defect and removing the defect using the magnetic force, it is possible to simultaneously use the rotational force and the magnetic force. Accordingly, defect removal efficiency can be improved.

According to some example embodiments of the present disclosure, a defect transporter may include a main body, an arm connected to the main body, a magnetic field generator connected to the arm, and a defect collecting unit connected to the magnetic field generator.

According to some example embodiments of the present disclosure, the main body is configured to move the defect collecting unit through a guide rail or a motor driving device, and the main body is configured to transmit collected data to a controller and receive a control signal from the controller.

The effects that can be obtained through the present disclosure are not limited to those described above. Technical effects not mentioned herein will be clearly understood by those skilled in the art from the description of the present disclosure described below.

### BRIEF DESCRIPTION OF THE DRAWINGS

The above and other objects, features and advantages of the present disclosure will become more apparent to those of ordinary skill in the art by describing in detail exemplary example embodiments thereof with reference to the accompanying drawings, in which:

FIG. 1 is a diagram provided to explain a defect removal device;

FIG. 2 is a flowchart provided to explain some example embodiments of a method for identifying a defect within a target object;

FIG. 3 is a diagram illustrating an example of a target object;

FIG. 4 is a diagram illustrating an example of a location of the identified defect within the target object;

FIG. 5 is a flowchart provided to explain some example embodiments of a method for depositing a ferromagnetic material layer on a defect;

FIG. 6 is a diagram provided to explain some example embodiments of a beam deposition device;

FIGS. 7 to 9 are diagrams provided to explain some example embodiments of a method for depositing a ferromagnetic material layer on a defect;

FIG. 10 is a flowchart provided to explain some example embodiments of a method for collecting a defect;

FIG. 11 is a diagram provided to explain a defect transporter;

FIG. 12 is a diagram provided to explain some example embodiments of a method for removing a defect;

FIG. 13 is a diagram provided to explain some example embodiments of a method for collecting a defect;

FIG. 14 is a flowchart provided to explain a method for removing a defect according to some example embodiments;

FIG. 15 is a flowchart provided to explain a method for removing a defect according to some example embodiments; and

FIG. 16 is a flowchart provided to explain a method for removing a defect according to some example embodiments.

### DETAILED DESCRIPTION

Hereinafter, some example embodiments of the present disclosure will be described with reference to the drawings. Throughout the description, the same reference numerals may refer to the same components.

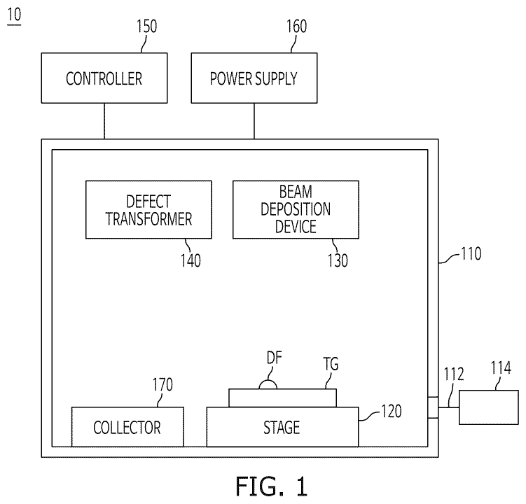

FIG. 1 is a diagram provided to explain a defect removal device.

Referring to FIG. 1, a defect removal device 10 may be configured to remove a defect DF on a target object TG. The target object TG may include, for example, a semiconductor wafer, a display panel, an optical lens, or a mask. In addition, the defect DF may include impurities or fine particles present on a surface or inside the target object TG. The defect DF may include various types of foreign materials, such as metal particles, organic materials, oxides, or fine dust. However, example embodiments are not limited thereto.

The defect removal device may be configured to deposit a ferromagnetic material layer on the defect DF in the target object TG and remove the defect DF with the deposited ferromagnetic material layer from the target object TG using a magnetic force. Referring to FIG. 1, the defect removal device 10 may include a chamber 110, a stage 120, a beam deposition device 130, a defect transporter 140, a controller 150, a power supply 160, and a collector 170.

The chamber 110 may provide an enclosed space where a defect removal process is performed. For example, the beam deposition device 130, the defect transporter 140, etc. may be disposed inside the chamber 110. The chamber 110 may include a metal material such as stainless steel, an aluminum alloy, or a non-metal material such as ceramic, but example embodiments are not limited thereto.

While the defect removal process is performed, the internal space of the chamber 110 may be maintained in a vacuum state. An exhaust pipe 112 may be connected to one side wall of the chamber 110. The exhaust pipe 112 may provide a path through which air is discharged by the vacuum pump 114 from inside the chamber to the outside.

The chamber 110 may be connected to the controller 150. The controller 150 may be configured to control components associated with the operation of the chamber 110. For example, the controller 150 may adjust the internal environment of the chamber 110 by controlling an opening and closing element disposed on an outer wall of the chamber 110. In addition, the controller 150 may control the vacuum pump 114 to convert and maintain the internal space of the chamber 110 in a vacuum state.

The target object TG may be seated on the stage 120. The stage 120 may be configured to load the target object TG into the chamber 110 and adjust the position of the target object TG. For example, the stage 120 may move the target object TG into the chamber 110 through a guide rail or a motor driving device. The stage 120 may be configured to be moved linearly, rotated, or moved around multiple axes inside the chamber 110, allowing the target object TG to be moved to a specific position.

The stage 120 may be connected to the controller 150. The controller 150 may be configured to control the movement path and position of the stage 120.

The beam deposition device 130 may deposit a ferromagnetic material layer on the defect DF. For example, the beam deposition device 130 may be a Focused Electron Beam Induced Deposition (FEBID) or a Focused Ion Beam Induced Deposition (FIBID), but example embodiments are not limited thereto. The ferromagnetic material layer may include at least one of iron (Fe), cobalt (Co), nickel (Ni), and a steel alloy, or a combination of these. However, example embodiments are not limited to the above.

The defect transporter 140 may remove the defect DF with the deposited ferromagnetic material layer from the target object TG using a magnetic force. The defect transporter 140 may refer to a device configured to generate a magnetic force with the electromagnetic induction method. For example, the defect transporter 140 may be configured to generate a static or variable magnetic field, and may be configured to adjust strength of the magnetic force according to the location and material properties of the defect DF. Meanwhile, the defect transporter 140 may include a magnetic material to generate a magnetic force, but example embodiments are not limited thereto.

The controller 150 may be configured to control and/or monitor each component of the defect removal device. For example, the controller 150 may control operation of the beam deposition device 130 and/or the defect transporter 140 based on manually and/or automatically set operating parameters (e.g., output intensity, operation time, position adjustment, etc.).

The controller 150 may include a processor and a memory. For example, the controller 150 may be a computing system such as a personal computer, a mobile phone, or a server, a module including a plurality of processing cores and memories mounted on a substrate as independent packages, or a system-on-chip (SoC) integrated into a single chip. However, example embodiments are not limited thereto.

The processor may communicate with the memory and execute instructions. The processor may be designed to execute a program (a set of instructions) stored in the memory. The processor may be implemented as an application processor (AP), a communication processor (CP), a central processing unit (CPU), a graphic processing unit (GPU), or a processor core, and may be any hardware capable of independently processing instructions. However, example embodiments are not limited thereto.

The memory is accessible to the processor and may store various software elements such as software programs, applications, operating systems (OS), or firmware. The memory may include various types of storage media such as Read-Only Memory (ROM), Random-Access Memory (RAM), flash memory, Dynamic Random Access Memory (DRAM), phase change memory, or ferroelectric memory, and may be implemented in a single form or a combination of these. However, example embodiments are not limited thereto.

The operation of the controller 150 may be implemented as instructions that can be read and executed by one or more processors, and the instructions may be stored in a computer-readable non-transitory storage medium.

The “computer-readable medium” may include any type of storage medium accessible by a computer, such as Read-Only Memory (ROM), Random-Access Memory (RAM), Hard Disk Drive, Compact Disk (CD), or Digital Video Disk (DVD). Further, the “non-transitory” computer-readable medium excludes wired, wireless, optical, or other communication links that transmit temporary electrical or other signals, and may include a medium designed to store or rewrite data permanently. For example, the non-transitory medium may include rewritable optical disks, erasable memory devices, or storage media where data can be overwritten after being stored.

The controller 150 of FIG. 1 is illustrated as an independent component separate from an individual component such as the beam deposition device 130 or the defect transporter 140, but example embodiments are not limited thereto. As needed, the controller 150 may be integrated into the individual component such as the beam deposition device 130 or the defect transporter 140 and implemented as an internal component of the corresponding device.

The power supply 160 may be configured to supply power to each component of the defect removal device 10. For example, the power supply 160 may apply power to the beam deposition device 130, the defect transporter 140, the controller 150, and the stage 120.

The power supply 160 may be configured to communicate with the controller 150, allowing the controller 150 to control power supply to the defect transporter 140 through the power supply 160. For example, the controller 150 may control the magnetic field generation intensity and operation state of the defect transporter 140 by adjusting the power applied to the defect transporter 140. Further, the controller 150 may perform a protective function by monitoring the power supply status in real time to reduce and/or prevent overvoltage, overcurrent, or other power abnormalities.

The power supply 160 of FIG. 1 is illustrated as an independent component separate from an individual component such as the beam deposition device 130 or the defect transporter 140, but example embodiments are not limited thereto. As needed, the power supply 160 may be integrated into the individual component such as the beam deposition device 130 or the defect transporter 140 and implemented as an internal component of the corresponding device.

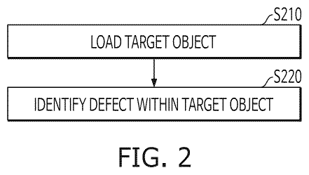

FIGS. 2 to 4 are views for explaining a method for identifying a defect within a target object. FIG. 2 is a flowchart provided to explain an example of a method for identifying a defect within a target object.

Referring to FIG. 2, the defect removal device (e.g., the defect removal device of FIG. 1) may load the target object (e.g., the target object TG of FIG. 1) into a chamber (e.g., the chamber 110 of FIG. 1), at S210. The controller (e.g., the controller 150 of FIG. 1) may control an opening and closing element attached to a stage (e.g., the stage 120 of FIG. 1) and the chamber to load the target object into the chamber.

The defect removal device may identify a defect within the target object loaded into the chamber, at S220. The controller may obtain information about the defect within the target object. The controller may control the beam deposition device (e.g., the beam deposition device 130 of FIG. 1) to detect a defect within the target object. For example, the controller may use the beam deposition device to irradiate a specific area of the target object with a beam, detect a reflected material to sense the location of the defect, or collect data for analyzing defect characteristics. The information about the defect may include information such as location, size, type, or material of the defect. Meanwhile, a sensor may be provided separately from the beam deposition device to detect information on coupling, but example embodiments are not limited thereto.

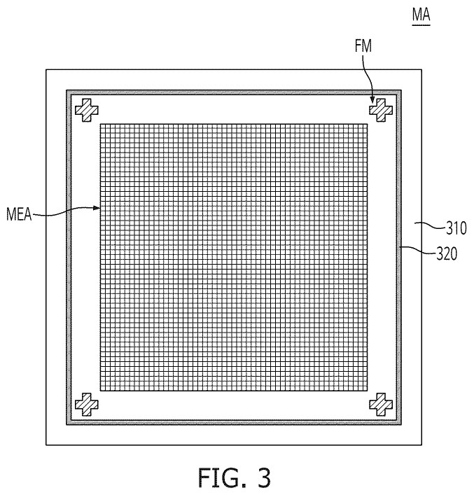

FIG. 3 is a diagram illustrating an example of a target object.

The target object (e.g., the target object TG of FIG. 1) may include a mask MA. For example, referring to FIG. 3, the mask MA may include a mask substrate 310, a plurality of patterns formed in a main exposure area MEA, a reference mark FM, and a dummy pattern 320.

The mask substrate 310 may include glass, silicon (Si), quartz, etc. However, the material of the mask substrate 310 is not limited to the materials described above, and various materials may be used according to design and manufacturing requirements.

A plurality of patterns may be disposed in the main exposure area MEA. The plurality of patterns may include a shape such as a line & space pattern that extends in one direction, and/or a specific shape such as a circle or polygon. The plurality of patterns may include one or more hole patterns. For example, one or more hole patterns may have an open space surrounded by a pattern structure.

The plurality of patterns disposed in the main exposure area MEA may include a light shielding film, or a reflective layer and an absorptive layer.

For example, the light shielding film may include a material containing chromium. Further, the reflective layer may have a multilayer structure in which two material layers are alternately stacked. For example, it may include a material layer containing molybdenum (Mo) and a material layer containing silicon (Si).

Further, the absorptive layer may include a material that absorbs the light incident on the absorptive layer, for example, EUV light. For example, the absorptive layer may include TaN, TaHf, TaHfN, TaBSi, TaBSiN, TaB, TaBN, TaSi, TaSiN, TaGe, TaGeN, TaZr, TaZrN, or a combination thereof.

However, the above description of the material used for the light shielding film, the reflective layer, and the absorptive layer is illustrative and example embodiments are not limited thereto. Each component may be replaced with a different material or structure depending on design requirements, manufacturing processes, or final application fields.

A dummy pattern 320 may be disposed outside the main exposure area MEA. The dummy pattern 320 may be, for example, a black border, but example embodiments are not limited thereto. The dummy pattern 320 may surround the main exposure area MEA. For example, the dummy pattern 320 may surround the main exposure area MEA in the form of a frame. For example, the dummy pattern 320 may include the same material as the plurality of patterns disposed in the main exposure area MEA.

The reference mark FM may be a mark that may be used as a reference for defect coordinates when the defect inspection device inspects a defect on the mask MA. The reference mark FM may not be used directly when a pattern is generated on a substrate, e.g., a semiconductor wafer, using the mask MA. The reference mark FM may have a shape of, for example, a dot mark, a substantially cross mark, or a square mark. However, example embodiments are not limited to the above. Since the mask MA includes the reference mark FM, the position coordinates of the defect obtained by the defect inspection may be related to the position coordinates of the reference mark FM. Accordingly, the location of the defect on the mask MA may be specified. The reference mark FM may also be referred to as an alignment mark.

FIG. 3 illustrates an example in which the reference mark FM is disposed near each of four corners, but this is illustrative, and the number and position of the reference marks FM are not limited thereto. The reference mark FM may be disposed in various numbers and positions according to design requirements or characteristics of the defect inspection device.

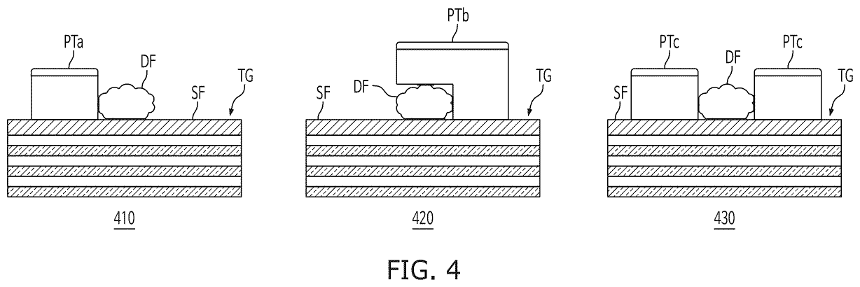

FIG. 4 is a diagram illustrating an example of a location of the identified defect within the target object.

Referring to FIG. 4, the defect DF may be disposed on a sidewall of the pattern structures PTa, PTb, PTc of the target object TG and on a target object surface SF. For example, the defect DF may be inserted and disposed in an open space formed by one or more hole patterns and/or protruding patterns. The defect DF may be in contact with the sidewall of one or more pattern structures PTa, PTb, PTc that form the hole patterns and/or the protruding pattern, and may be in contact with the target object surface SF.

First to third examples 410, 420, 430 represent various arrangements of defect DF within the target object TG.

The first example 410 illustrates that the defect DF is disposed on one side of the first pattern structure PTa. The defect DF may be attached to the target object surface SF and a sidewall of the first pattern structure Pta adjacent thereto.

The second example 420 illustrates that the second pattern structure Ptb, to which the defect DF is attached, has a shape that covers an upper surface of the defect DF. The second pattern structure PTb may include a portion protruding in a vertical direction from the target object surface SF and a portion extending from an end of the protruding portion parallel to the target object surface SF. For example, the defect DF may be attached to the target object surface SF and one side of the second pattern structure Ptb adjacent thereto, and the defect DF and the horizontally extended portion of the second pattern structure PTb may overlap in the vertical direction. In some example embodiments, the defect DF may be attached to the target object surface SF, one side surface of the second pattern structure Ptb adjacent thereto, and a lower surface of the horizontally extended portion of the second pattern structure PTb.

The third example 430 illustrates that the third pattern structures PTc to which the defect DF is attached are disposed on both sides of the defect DF. The third pattern structure PTc may be a hole pattern structure that surrounds the defect DF, or the third pattern structures PTc may be separate protruding pattern structures that are spaced apart from each other in a horizontal direction. For example, the defect DF may be simultaneously attached to the target object surface SF and to inner walls of the third pattern structures PTc, which are spaced apart from each other in the horizontal direction.

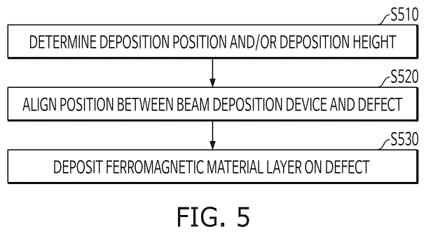

FIGS. 5 to 9 are diagrams provided to explain a method for depositing a ferromagnetic material layer on the defect. FIG. 5 is a flowchart provided to explain an example of the method for depositing the ferromagnetic material layer on the defect.

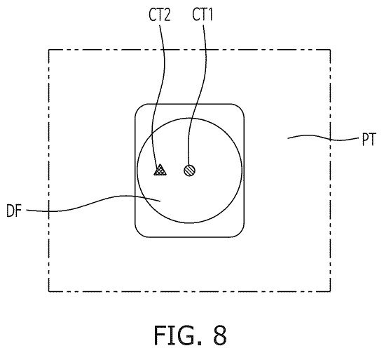

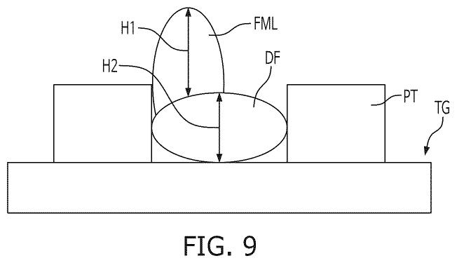

Referring to FIG. 5, the defect removal device (e.g., the defect removal device of FIG. 1) may determine a deposition position and/or a deposition height of the ferromagnetic material layer, at S510. For example, the controller (e.g., the controller 150 of FIG. 1) may determine the deposition position and/or the deposition height of the ferromagnetic material layer based on the information about the defect within the target object which is obtained through the method described with reference to FIG. 2. Details of the method for determining the deposition position and/or the deposition height of the ferromagnetic material layer will be described below with reference to FIGS. 8 and 9.

The defect removal device may arrange a position between the beam deposition device (e.g., the beam deposition device 130 of FIG. 1) and the defect, at S520. For example, the controller may position the beam deposition device to align with the deposition position. The controller may control the beam deposition device such that an electron gun, a gas injector, etc. of the beam deposition device (to be described below) are aligned towards the deposition position.

The defect removal device may deposit a ferromagnetic material layer on the defect, at S530. For example, based on manually and/or automatically set operating parameters (e.g., output intensity, operation time, position adjustment, etc.), the controller may selectively deposit the deposition material on the defect by irradiating a beam at the deposition position within the target object and ejecting gas including precursors of the deposition material.

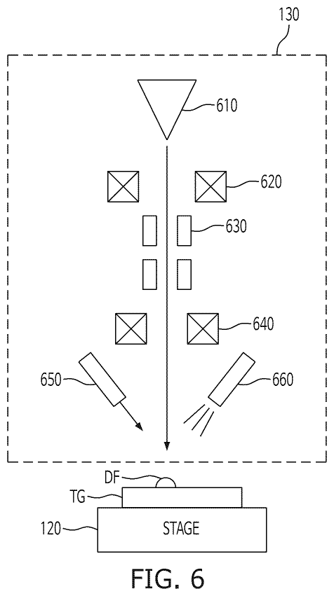

FIG. 6 is a diagram provided to explain a beam deposition device.

Referring to FIG. 6, the beam deposition device 130 may include an electron gun 610, a focusing lens 620, a deflector 630, an objective lens 640, a detector 650, and a gas injector 660.

The electron gun 610 may generate and emit an electron beam. The wavelength of the electron beam may be determined by energy of electrons emitted from the electron gun 610. The wavelength of the electron beam may be several nanometers. The electron gun 610 may be any one of a Cold Field Emission (CFE) type, a Schottky Emission (SE) type, or a Thermal Emission (TE) type. However, example embodiments are not limited thereto.

The electron gun 610 may generate an electron beam by providing energy above a work function to electrons of a solid electron source thermally or electrically. The work function may refer to a difference between the energy level in the vacuum and the Fermi energy.

The focusing lens 620 may be disposed in the path of the electron beam between the electron gun 610 and the target object TG. The focusing lens 620 may focus an electron beam on the deflector 630.

The deflector 630 may be positioned between the focusing lens 620 and the target object TG, and adjust the electron beam emitted from the electron gun 610. The deflector 630 may deflect the electron beam through the focusing lens 620 and the objective lens 640 to a set deposition position on the target object TG. Further, the deflector 630 may scan an electron beam on the target object TG. The deflector 630 may be either an electric type or a magnetic type.

The objective lens 640 may be positioned between the deflector 630 and the target object TG, and focus the electron beam on the deposition position of the target object TG. Since the electron beam is confined to a narrow area on the target object TG, the accuracy of the beam deposition device 130 may be improved.

The detector 650 may detect some of the electrons reflected or emitted from the target object TG. Therefore, it is possible to analyze the state of the target object TG or provide feedback data (e.g., information on defect, detected image, etc.).

The gas injector 660 may eject gas including the precursors of the deposition material used in the electron beam deposition process to the target object TG. The gas may include a material such that the deposition material is selectively deposited on the defect area through interaction with the electron beam. The deposition material may include a ferromagnetic material such as iron (Fe), cobalt (Co), or nickel (Ni). In addition, the gas including the precursors may include a compound that can be converted into the deposition material. For example, for iron-based materials, the precursors may include metal-organic compounds such as iron carbonyl (Fe(CO)₅). For cobalt (Co) or nickel (Ni), the precursors may include a compound such as cobalt carbonyl (Co₂(CO)₈) or nickel carbonyl (Ni(CO)₄). However, example embodiments are not limited thereto.

The focusing lens 620, the deflector 630, and the objective lens 640 described above are non-limiting examples of the electron beam transfer system and do not limit the technical idea of the present disclosure. Based on this description, a person skilled in the art may design an electron beam transfer system including additional features, such as a focusing lens and a deflector, for example.

FIG. 6 illustrates an example in which the beam deposition device 130 is the Electron Beam Induced Deposition (EBID) device, but this is only provided for convenience of explanation. The beam deposition device 130 may be implemented as an Ion Beam Induced Deposition (IBID) device.

For the IBID device, the electron gun 610 may be replaced with an ion source that generates an ion beam. The ion source may generate an ion beam through a plasma discharge or ionization process, which may be directed to the target object TG. However, example embodiments are not limited thereto.

In addition, as an alternative to the focusing lens 620, an electric or magnetic field-based ion focusing system may be used. Similar to the case of the electron beam, the deflector 630 may perform the role of controlling or scanning the path of the ion beam. The objective lens 640 may perform the role of precisely focusing the ion beam on a specific position of the target object TG. The detector 650 may detect ions, electrons, or other signals reflected or emitted from the target object TG and provide a process feedback (e.g., information on defect, detection image, etc.). The gas injector 660 may be used in the same way in the ion beam deposition process, and may eject gas including precursors of the deposition material onto the target object TG.

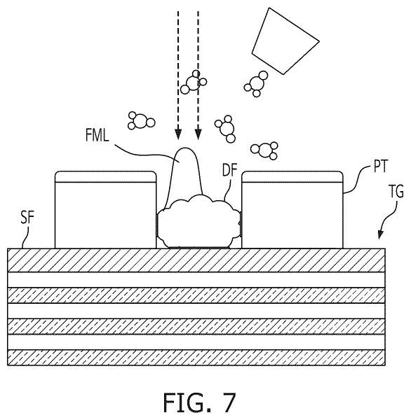

FIGS. 7 to 9 are diagrams provided to explain a method for depositing a ferromagnetic material layer on a defect.

The beam deposition device (e.g., the beam deposition device 130 of FIGS. 1 and 6) may deposit the ferromagnetic material layer FML on the defect DF within the target object TG. Referring to FIG. 7, the defect DF may be attached to the target object surface SF and disposed between the pattern structures PT of the target object TG.

The beam deposition device may determine a deposition position of the ferromagnetic material layer FML. The controller (e.g., the controller 150 of FIG. 1) may determine the deposition position of the ferromagnetic material layer FML based on the information about the identified defect DF. The controller may deposit the ferromagnetic material layer FML on the determined deposition position using a beam deposition device.

Referring to FIG. 8, the controller may obtain a first coordinate CT1 indicating a center position of the defect DF from the information about the defect DF. The controller may determine the deposition position of the ferromagnetic material layer FML by applying a desired (and/or alternatively predetermined) offset distance in the horizontal direction from the center of the defect DF (e.g., the first coordinate CT1). The deposition position may be defined by a second coordinate CT2.

The offset distance may be determined based on the information about the defect DF, e.g., the first coordinate CT1 of the defect and information about a width of the defect. For example, the offset distance may be determined as half the distance between the center of the defect DF (the first coordinate CT1) and a side surface of the defect DF. However, example embodiments are not limited to the above, and the method for determining the offset distance and deposition position may be modified according to various design and process requirements.

Additionally or alternatively, the beam deposition device may determine a deposition height of the ferromagnetic material layer FML. The controller may determine the deposition height of the ferromagnetic material layer FML based on the information about the defect DF. Using the beam deposition device, the controller may deposit the ferromagnetic material layer FML at the determined deposition position and deposition height.

Referring to FIG. 9, the controller may determine a first height H1, which is the deposition height of the ferromagnetic material layer FML, based on the information of the identified defect DF. The controller may obtain, from the information about the defect DF, a second height H2 indicating a height of the defect DF. The controller may determine the first height H1, which is the deposition height, to be greater than the second height H2, which is the height of the defect DF. The beam deposition device may deposit the ferromagnetic material layer FML at the determined deposition position and at the deposition height, for example, the first height H1.

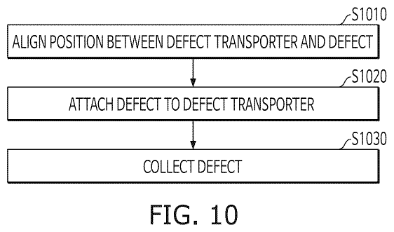

FIGS. 10 to 13 are diagrams provided to explain a method for collecting a defect. FIG. 10 is a flowchart provided to explain an example of a method for collecting a defect.

Referring to FIG. 10, the defect removal device (e.g., the defect removal device of FIG. 1) may align a position between the defect transporter and the defect, at S1010. For example, the controller may position the defect transporter to align with the deposition position and/or the defect position. The controller may control such that the defect collecting unit of the defect transporter (to be described below) is aligned towards the deposition position and/or the defect position.

The defect removal device may attach the defect to the defect transporter, at S1020. For example, the controller may generate a magnetic force in the defect collecting unit included in the defect transporter, and control the ferromagnetic material layer to adhere to the defect collecting unit using the magnetic force.

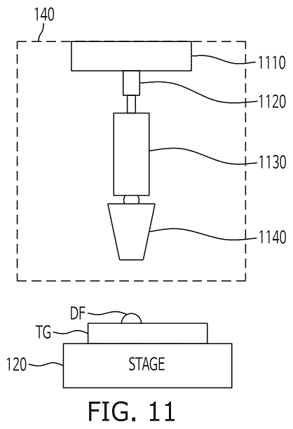

The defect removal device may collect the defect, at S1030. For example, the controller may position the defect transporter on the collector (e.g., the collector 170 of FIG. 11) and deactivate the magnetic force applied to the defect transporter so that the defect with the deposited ferromagnetic material layer is dropped onto the collector.

FIG. 11 is a diagram provided to explain a defect transporter.

Referring to FIG. 11, the defect transporter 140 may include a main body 1110, an arm 1120 connected to the main body 1110, a magnetic field generator 1130 connected to the arm 1120, and a defect collecting unit 1140 connected to the magnetic field generator 1130.

The main body 1110 may be configured to move the defect collecting unit 1140 through a guide rail or a motor driving device. The main body 1110 may include a control module, a signal module, a sensor module, etc., which may be connected to the controller (the controller 150 of FIG. 1). Using the control module, the signal module, and the sensor module, the main body 1110 may transmit the collected data to the controller or receive a control signal from the controller.

The arm 1120 may be connected to a portion of the main body 1110 and designed to vertically move the defect collecting unit 1140. For example, the arm 1120 may include a hydraulic structure to move in a vertical direction of the defect collecting unit 1140.

The magnetic field generator 1130 is configured to receive the power through the main body 1110 and generate a magnetic field. For example, the magnetic field generator 1130 may include an electromagnetic coil or a permanent magnet. However, the example embodiments are not limited to the above, and various types of magnetic field generating devices may be applied.

The defect collecting unit 1140 may be configured to receive the magnetic field from the magnetic field generator 1130 and generate a magnetic force. Upon application of the power to the magnetic field generator 1130, a magnetic field may also be generated in the defect collecting unit 1140, enabling it to collect the defect DF with the deposited ferromagnetic material layer. The defect collecting unit 1140 may have a specific shape to effectively collect the defect DF. For example, an end of the defect collecting unit 1140 may have a shape parallel to a surface of the stage (e.g., the stage 120 of FIG. 1). Alternatively, the defect collecting unit 1140 may be designed in various shapes including polygons, circles, etc., and modified appropriately depending on the process requirements.

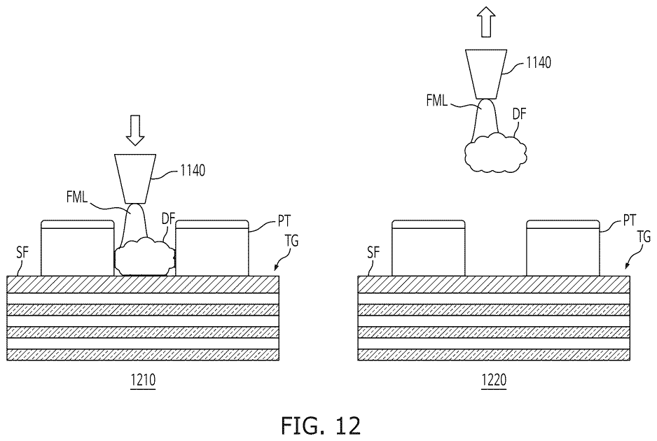

FIG. 12 is a diagram provided to explain a method for removing a defect.

Referring to FIG. 12, the defect removal device (e.g., the defect removal device of FIG. 1) may remove the defect DF with the deposited ferromagnetic material layer FML from the target object TG using the defect transporter.

First and second operations 1210, 1220 illustrate an example of removing the defect DF with the deposited ferromagnetic material layer FML from the target object TG using the defect collecting unit 1140.

Referring to the first operation 1210, the controller may position the defect collecting unit 1140 near to the ferromagnetic material layer FML. For example, the controller may move the defect collecting unit 1140 through a guide rail or a motor driving device, and position the defect collecting unit 1140 near to the ferromagnetic material layer FML.

The controller may determine if the ferromagnetic material layer FML is attached to the defect collecting unit 1140. For example, the controller may determine whether the ferromagnetic material layer FML is attached using at least one of electrical signal detection, magnetic sensor detection, optical detection, mechanical sensor detection, and ultrasonic sensor detection.

To this end, one or more sensors may be provided in the defect transporter, for example, in the defect collecting unit 1140. For example, at least one of an electrical signal detection sensor, a magnetic sensor, an optical sensor, a mechanical sensor, an ultrasonic sensor, or an image sensor may be included. However, example embodiments are not limited to the above.

Referring to the second operation 1220, in response to determining that the ferromagnetic material layer FML is attached to the defect collecting unit 1140, the controller may retract the defect collecting unit 1140. Using the defect collecting unit 1140 in which the magnetic force is generated, the controller may remove the ferromagnetic material layer FML deposited at a position offset from the center of the defect DF in the horizontal direction. By utilizing both the rotational force and the magnetic force, the defect DF on the target object TG can be further effectively removed in this process.

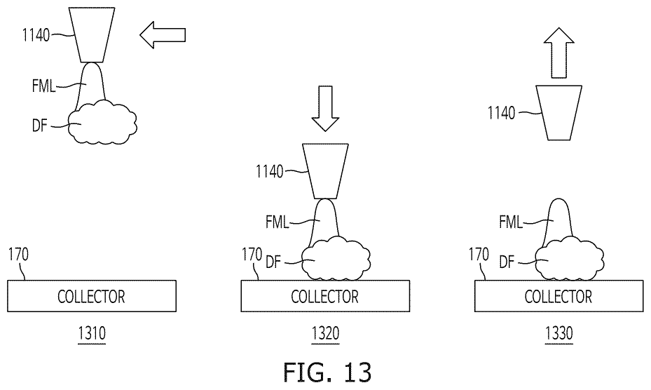

FIG. 13 is a diagram provided to explain a method for collecting a defect.

Referring to FIG. 13, the defect removal device (e.g., the defect removal device of FIG. 1) may move the defect DF with the deposited ferromagnetic material layer FML to the collector 170 using the defect transporter.

First to third operations 1310, 1320, 1330 illustrate an example of operations of moving the defect DF with the deposited ferromagnetic material layer FML, which has been removed from the target object TG, to the collector 170 using the defect collecting unit 1140.

Referring to the first operation 1310 and the second operation 1320, the controller may cause the defect collecting unit 1140 to approach an upper portion of the collector 170. For example, the controller may cause the defect collecting unit 1140 to be moved through a guide rail or a motor driving device, and cause the defect collecting unit 1140 to be moved near to the collector 170.

Referring to the third operation 1330, the controller may deactivate the magnetic force generated in the defect collecting unit 1140 so that the defect DF with the deposited ferromagnetic material layer FML is dropped onto the collector 170. If the magnetic force is deactivated, the defect DF with the deposited ferromagnetic material layer FML, which is attached to the defect collecting unit 1140, may be separated from the defect collecting unit 1140 and dropped onto the collector 170.

The controller may skip a process in which the defect collecting unit 1140 is moved near to the collector 170 (e.g., the second operation 1320), and deactivate the magnetic force of the defect collecting unit 1140 while the defect collecting unit 1140 and the collector 170 are aligned so that the defect DF with the deposited ferromagnetic material layer FML is moved to the collector 170.

Accordingly, the defect collecting unit 1140 may be maintained for reuse. The defect collecting unit 1140 may easily separate the defect DF by deactivating the magnetic field transmitted from the magnetic field generator (e.g., the magnetic field generator 1130 of FIG. 11). In this process, the surface of the collecting unit may be kept free of residual magnetism or impurities, allowing for repeated use.

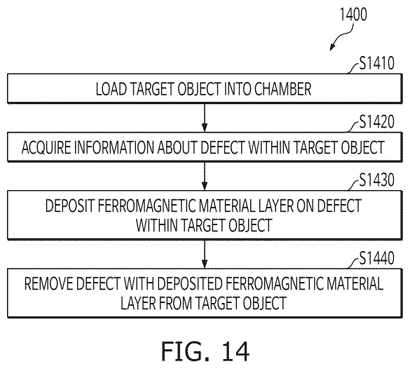

FIG. 14 is a flowchart provided to explain a method for removing a defect.

Referring to FIG. 14, a method 1400 for removing a defect may be performed by the defect removal device (e.g., the defect removal device of FIG. 1, or the controller 150 of the defect removal device). The defect removal device may include a chamber, a stage, a beam deposition device, a defect transporter, a controller, a power supply, and a collector.

The defect removal device may load the target object into the chamber, at S1410.

The defect removal device may acquire information about a defect within the target object, at S1420. For example, the information about the defect may include a center position of the defect. In another example, the information about the defect may include a height of the defect.

The defect removal device may deposit a ferromagnetic material layer on the defect within the target object, at S1430. For example, the ferromagnetic material layer may include at least one of iron (Fe), cobalt (Co), and nickel (Ni). However, example embodiments are not limited thereto.

The defect removal device may determine a deposition position of the ferromagnetic material layer. For example, the defect removal device may determine the deposition position of the ferromagnetic material layer by applying a desired (and/or alternatively predetermined) offset distance in the horizontal direction from the center position of the defect. The defect removal device may deposit a ferromagnetic material layer at the determined deposition position using the beam deposition device.

The defect removal device may determine the deposition position and a deposition height of the ferromagnetic material layer. For example, the defect removal device may determine the deposition height to be greater than the height of the defect. The defect removal device may deposit the ferromagnetic material layer at the determined deposition position and the determined deposition height using the beam deposition device.

The defect removal device may remove the defect with the deposited ferromagnetic material layer from the target object, at S1440. The defect removal device may generate a magnetic force in the defect collecting unit included in the defect transporter and attach a ferromagnetic material layer to the defect collecting unit. For example, the defect removal device may cause the defect collecting unit to approach the ferromagnetic material layer. The defect removal device may determine whether the ferromagnetic material layer is attached to the defect collecting unit. For example, the defect removal device may determine whether the ferromagnetic material layer is attached using at least one of electrical signal detection, magnetic sensor detection, optical detection, mechanical sensor detection, and ultrasonic sensor detection. In response to the determining that the ferromagnetic material layer is attached to the defect collecting unit, the defect removal device may retract the defect collecting unit.

Additionally, the defect removal device may move the defect with the deposited ferromagnetic material layer to the collector. For example, the defect removal device may position the defect collecting unit, to which the defect with the deposited ferromagnetic material layer is attached, on the collector. The defect removal device may deactivate the magnetic force generated in the defect collecting unit so that the defect with the deposited ferromagnetic material layer is dropped onto the collector.

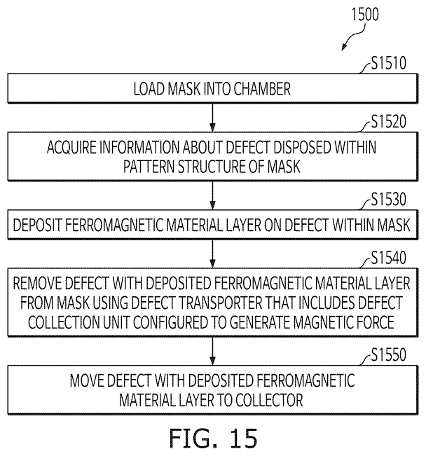

FIG. 15 is a flowchart provided to explain a method for removing a defect according to some example embodiments.

Referring to FIG. 15, a method 1500 for removing a defect may be performed by the defect removal device (e.g., the defect removal device of FIG. 1, or the controller 150 of the defect removal device). The defect removal device may include a chamber, a stage, a beam deposition device, a defect transporter, a controller, a power supply, and a collector.

The defect removal device may load a mask into the chamber, at S1510.

The defect removal device may acquire information about a defect disposed within the pattern structure of the mask, at S1520. For example, the information about the defect may include a center position of the defect. In another example, the information about the defect may include a height of the defect.

The defect removal device may deposit a ferromagnetic material layer on the defect in the mask, at S1530. For example, the ferromagnetic material layer may include at least one of iron (Fe), cobalt (Co), and nickel (Ni). However, example embodiments are not limited thereto.

The defect removal device may determine a deposition position of the ferromagnetic material layer. For example, the defect removal device may determine the deposition position of the ferromagnetic material layer by applying a desired (and/or alternatively predetermined) offset distance in the horizontal direction from the center position of the defect. The defect removal device may deposit a ferromagnetic material layer at the determined deposition position.

The defect removal device may determine the deposition position and a deposition height of the ferromagnetic material layer. For example, the defect removal device may determine the deposition height to be greater than the height of the defect. The defect removal device may deposit the ferromagnetic material layer at the determined deposition position and the determined deposition height using the beam deposition device.

The defect removal device may remove the defect with the deposited ferromagnetic material layer from the mask using the defect transporter that includes the defect collecting unit configured to generate a magnetic force, at S1540. The defect removal device may generate a magnetic force in the defect collecting unit and cause the defect collecting unit to approach the ferromagnetic material layer. The defect removal device may determine whether the ferromagnetic material layer is attached to the defect collecting unit. For example, the defect removal device may determine whether the ferromagnetic material layer is attached using at least one of electrical signal detection, magnetic sensor detection, optical detection, mechanical sensor detection, and ultrasonic sensor detection. In response to the determining that the ferromagnetic material layer is attached to the defect collecting unit, the defect removal device may retract the defect collecting unit.

The defect removal device may move the defect with the deposited ferromagnetic material layer to the collector, at S1550. For example, the defect removal device may position the defect collecting unit, to which the defect with the deposited ferromagnetic material layer is attached, on the collector. The defect removal device may deactivate the magnetic force generated in the defect collecting unit so that the defect with the deposited ferromagnetic material layer is dropped onto the collector.

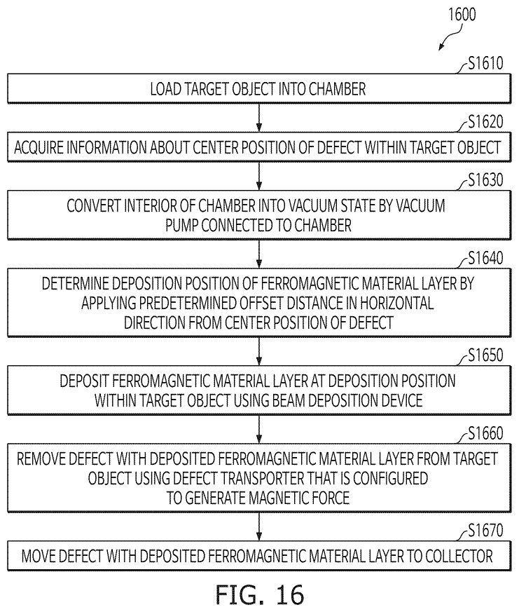

FIG. 16 is a flowchart provided to explain a method for removing a defect according to some example embodiments.

Referring to FIG. 16, a method 1600 for removing a defect may be performed by the defect removal device (e.g., the defect removal device of FIG. 1, or the controller 150 of the defect removal device). The defect removal device may include a chamber, a stage, a beam deposition device, a defect transporter, a controller, a power supply, and a collector.

The defect removal device may load the target object into the chamber, at S1610.

The defect removal device may acquire information about a defect within the target object, at S1620. The defect removal device may convert the interior of the chamber to a vacuum state by a vacuum pump connected to the chamber, at S1630. The defect removal device may determine the deposition position of the ferromagnetic material layer by applying a desired (and/or alternatively predetermined) offset distance in the horizontal direction from the center position of the defect, at S1640. The defect removal device may deposit a ferromagnetic material layer at the deposition position within the target object using the beam deposition device, at S1650. The defect removal device may remove the defect with the deposited ferromagnetic material layer from the target object using the defect transporter that is configured to generate a magnetic force, at S1660. The defect removal device may move the defect with the deposited ferromagnetic material layer to the collector, at S1670.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Although non-limiting example embodiments of the present disclosure have been described above with reference to the accompanying drawings, the example embodiments of the present disclosure are not limited thereto, and various changes and modifications can be made without departing from the spirit and scope of the present disclosure.

1. A method for removing a defect, comprising:
loading a target object into a chamber;
acquiring information about the defect on the target object;
depositing a ferromagnetic material layer on the defect; and
removing the defect and the deposited ferromagnetic material layer from the target object.

2. The method according to claim 1, wherein the depositing the ferromagnetic material layer comprises:
determining a deposition position of the ferromagnetic material layer; and
depositing the ferromagnetic material layer at the determined deposition position using a beam deposition device.

3. The method according to claim 2, wherein
the information about the defect includes a center position of the defect, and
the determining the deposition position of the ferromagnetic material layer comprises applying an offset distance in a horizontal direction from the center position of the defect.

4. The method according to claim 1, wherein the depositing the ferromagnetic material layer comprises:
determining a deposition position and a deposition height of the ferromagnetic material layer; and
depositing the ferromagnetic material layer at the determined deposition position and the determined deposition height using a beam deposition device.

5. The method according to claim 4, wherein
the information about the defect includes a height of the defect, and
in the determining of the deposition position and the deposition height of the ferromagnetic material layer, the determined deposition height is greater than the height of the defect.

6. The method according to claim 1, wherein the removing the defect comprises:
generating a magnetic force in a defect collecting unit included in a defect transporter; and
attaching the ferromagnetic material layer to the defect collecting unit.

7. The method according to claim 6, wherein the attaching the ferromagnetic material layer comprises:
moving the defect collecting unit to approach the ferromagnetic material layer;
determining whether the ferromagnetic material layer is attached to the defect collecting unit; and
retracting the defect collecting unit in response to the determining that the ferromagnetic material layer is attached to the defect collecting unit.

8. The method according to claim 7, wherein the determining whether the ferromagnetic material layer is attached comprises using at least one of electrical signal detection, magnetic sensor detection, optical detection, mechanical sensor detection, and ultrasonic sensor detection.

9. The method according to claim 6, further comprising moving the defect with the deposited ferromagnetic material layer to a collector.

10. The method according to claim 9, wherein the moving the defect comprises:
positioning the defect collecting unit on the collector, the defect collecting unit being attached with the defect and the deposited ferromagnetic material layer; and
dropping the defect and the ferromagnetic material layer on the collector in response to deactivating the magnetic force generated in the defect collecting unit.

11. The method according to claim 1, wherein the ferromagnetic material layer includes at least one of iron (Fe), cobalt (Co), and nickel (Ni).

12. A method for removing a defect, comprising:
loading a mask into a chamber;
acquiring information about the defect on a pattern structure of the mask;
depositing a ferromagnetic material layer on the defect;
removing the defect and the deposited ferromagnetic material layer from the mask using a defect transporter, the defect transporter including a defect collecting unit configured to generate a magnetic force; and
moving the defect and the deposited ferromagnetic material layer to a collector.

13. The method according to claim 12, wherein the depositing the ferromagnetic material layer comprises:
determining a deposition position of the ferromagnetic material layer; and
depositing the ferromagnetic material layer at the determined deposition position.

14. The method according to claim 13, wherein
the information about the defect includes a center position of the defect, and
the determining of the deposition position of the ferromagnetic material layer comprises applying an offset distance in a horizontal direction from the center position of the defect.

15. The method according to claim 12, wherein the depositing the ferromagnetic material layer comprises:
determining a deposition position and a deposition height of the ferromagnetic material layer; and
depositing the ferromagnetic material layer at the determined deposition position and the determined deposition height.

16. The method according to claim 15, wherein
the information about the defect includes a height of the defect, and
in the determining of the deposition position and the deposition height of the ferromagnetic material layer, the determined deposition height is greater than the height of the defect.

17. The method according to claim 12, wherein the removing the defect comprises:
generating the magnetic force in the defect collecting unit;
moving the defect collecting unit to approach the ferromagnetic material layer;
determining whether the ferromagnetic material layer is attached to the defect collecting unit; and
retracting the defect collecting unit in response to the determining that the ferromagnetic material layer is attached to the defect collecting unit.

18. The method according to claim 12, wherein the moving the defect comprises:
positioning the defect collecting unit on the collector, the defect collecting unit being attached with the defect and the deposited ferromagnetic material layer; and
dropping the defect and the ferromagnetic material layer on the collector in response to deactivating the magnetic force generated in the defect collecting unit.

19. The method according to claim 12, wherein the ferromagnetic material layer includes at least one of iron (Fe), cobalt (Co), nickel (Ni), and a steel alloy.

20. A method for removing a defect, comprising:
loading a target object into a chamber;
acquiring information about a center position of the defect on the target object;
converting an interior of the chamber into a vacuum state by pumping the interior of the chamber using a vacuum pump connected to the chamber;
determining a deposition position of a ferromagnetic material layer by applying an offset distance in a horizontal direction from the center position of the defect;
depositing the ferromagnetic material layer at the determined deposition position within the target object using a beam deposition device;
removing the defect and the deposited ferromagnetic material layer from the target object using a defect transporter, the defect transporter configured to generate a magnetic force; and
moving the defect and the deposited ferromagnetic material layer to a collector.
